(19) United States
(12) Patent Application Publication
(10) Pub. No.: US 2012/0040292 A1
(43) Pub. Date: Feb. 16, 2012

(54) TRANSFER METHOD, TRANSFER APPARATUS, AND METHOD OF MANUFACTURING ORGANIC LIGHT EMITTING ELEMENT

(75) Inventor: Kohji Hanawa, Kanagawa (JP)

(73) Assignee: SONY CORPORATION, Tokyo (JP)

(21) Appl. No.: 13/280,595

(22) Filed: Oct. 25, 2011

Related U.S. Application Data
(62) Division of application No. 12/123,803, filed on May 20, 2008.

(30) Foreign Application Priority Data
May 21, 2007 (JP) 2007-134211

(51) Int. Cl. G03F 7/20; G03B 27/00

(52) U.S. Cl. 430/319; 430/322; 355/18

(57) ABSTRACT

A transfer method and a transfer apparatus capable of making the shape and quality of a transferred layer uniform and a method of manufacturing an organic light emitting element. A transfer method includes a step of disposing a transfer substrate and an acceptor substrate so as to face each other, a transfer layer being provided on the transfer substrate, and a plurality of areas being arranged in the acceptor substrate, and transferring the transfer layer to the plurality of areas by emitting a radiation ray from the transfer substrate side. The radiation ray is shaped in a band shape, and a short-axis width in a center portion in a long-axis direction of the radiation ray is set to be larger than that in an end portion.

### RELATED APPLICATION DATA

This application is a division of U.S. patent application Ser. No. 12/123,803, filed May 20, 2008, the entirety of which is incorporated herein by reference to the extent permitted by law. The present application claims the benefit of priority to Japanese Patent Application No. JP 2007-134211 filed in the Japanese Patent Office on May 21, 2007, the entirety of which is incorporated by reference herein to the extent permitted by law.

### BACKGROUND OF THE INVENTION

The present invention relates to a transfer method and a transfer apparatus for transferring, for example, a transfer layer containing an organic light emitting material by laser radiation and to a method of manufacturing an organic light emitting element using the same.

Hitherto, in a process of manufacturing an organic light emitting element, a method of patterning an organic layer such as a light emitting layer by using a mask having an aperture corresponding to a predetermined area is generally used. In recent years, a large-sized organic light emitting element is manufactured and, in this case, a mask used for the patterning becomes also large. Due to the increase in size, deflection occurs in the mask, and precision of alignment deteriorates. There is consequently the possibility that the aperture ratio decreases. To address the disadvantage, methods of transferring an organic layer onto a substrate by emitting a laser beam to a transfer substrate on which the organic layer is deposited have been proposed (refer to, for example, Japanese Unexamined Patent Application Publication Nos. H09-167684 and 2002-216957 and Japanese Unexamined Patent Application Publication (Translation of PCT application) No. 2000-515083).

### SUMMARY OF THE INVENTION

Methods of reducing tact time by shaping a laser beam used for thermal transfer into a band shape and emitting the laser beam to a plurality of pixels in a lump have been also proposed (refer to, for example, Japanese Unexamined Patent Application Publication Nos. 2006-93127 and 2006-93077). Japanese Unexamined Patent Application Publication No. 2003-257641 proposes a method of preventing an organic layer from being transferred to an area other than a desired area by setting intensity in a center portion of an intensity distribution of a laser beam to be higher than that in an end portion.

However, in the above-described methods of the patent documents, the intensity distribution of a laser beam emitted to a plurality of pixels is nonuniform and, accordingly, the temperature distribution in an irradiated surface (transfer substrate) becomes nonuniform. Consequently, variations occur in the width, shape, film quality, and the like of an organic layer formed by transfer. As a result, a disadvantage arises such that unevenness occurs in luminance of light generated by an organic light emitting element.

It is therefore desirable to provide a transfer method and a transfer apparatus capable of making shape, quality, and the like of a transferred layer uniform, and a method of manufacturing an organic light emitting element.

According to an embodiment of the present invention, there is provided a first transfer method including a step of disposing a transfer substrate and an acceptor substrate so as to face each other, a transfer layer being provided on the transfer substrate, and a plurality of areas being arranged in the acceptor substrate, and transferring the transfer layer to the plurality of areas by emitting a radiation ray from the transfer substrate side. The radiation ray is shaped in a band shape, and a short-axis width in a center portion in a long-axis direction of the radiation ray is set to be larger than that in an end portion.

According to an embodiment of the present invention, there is provided a second transfer method including a step of disposing a transfer substrate and an acceptor substrate so as to face each other, a transfer layer being provided on the transfer substrate, and a plurality of areas being arranged in the acceptor substrate, and transferring the transfer layer to the plurality of areas by emitting a radiation ray from the transfer substrate side. The radiation ray is shaped in a band shape, and an intensity peak value in a center portion in a long-axis direction of the radiation ray is set to be smaller than that in an end portion.

In the first transfer method of the embodiment of the present invention, by irradiating the transfer substrate on which the transfer layer is provided with a band-shaped radiation ray, the transfer layer is transferred to the plurality of areas in the acceptor substrate in a lump. When the plurality of areas are irradiated with the radiation ray, heat is accumulated and temperature easily rises in the center portion more than that in the end portion. At this time, since the short-axis width in the center portion in the long-axis direction of the band-shaped radiation ray is larger than that in the end portion, occurrence of the temperature difference between the center portion and the end portion is suppressed, and the temperature distribution in the entire surface to be irradiated becomes uniform.

In the second transfer method of the embodiment of the present invention, by irradiating the transfer substrate on which the transfer layer is provided with a band-shaped radiation ray, the transfer layer is transferred to the plurality of areas in the acceptor substrate in a lump. When the plurality of areas are irradiated with the radiation ray, heat is accumulated and temperature easily rises in the center portion more than that in the end portion. At this time, since the intensity peak value in the center portion in the long-axis direction of the band-shaped radiation ray is smaller than that in the end portion, occurrence of the temperature difference between the center portion and the end portion is suppressed, and the temperature distribution in the entire surface to be irradiated becomes uniform.

According to an embodiment of the present invention, there is provided a transfer apparatus transferring a transfer layer formed on a transfer substrate to an acceptor substrate by irradiating the transfer substrate with a radiation ray and having an optical mechanism for emitting the radiation ray to the transfer substrate. The optical mechanism includes: a light source for emitting the radiation ray; an illumination lens for shaping the radiation ray to a band shape; a radiation ray splitter for splitting the radiation ray formed in the band shape by the illumination lens into a plurality of areas in a long-axis direction of the radiation ray; and an imaging lens for forming an image onto the transfer substrate from the radiation ray split by the radiation ray splitter. The imaging lens is constructed so that a deviation from a focal point in a center portion is larger than that in an end portion.

In the transfer apparatus according to the embodiment of the present invention, by a radiation ray emitted from the light source and shaped into a band shape by the illumination lens, an image is formed on the transfer substrate by the imaging lens. The imaging lens is constructed so that a deviation from the focal point in the center portion in the long-axis direction is larger than that in the end portion. With the configuration, the short-axis width in the center portion of the radiation ray by which an image is formed becomes larger than that in the end portion, and the intensity peak value in the center portion becomes smaller than that in the end portion. Thus, occurrence of the temperature difference between the center portion and the end portion is suppressed, and the temperature distribution in the entire surface to be irradiated becomes uniform.

The transfer apparatus further includes a position detector for detecting a position on the transfer substrate and a height detector for detecting a height from the transfer substrate of the imaging lens. The optical mechanism is allowed to perform a scan on the basis of the position detected by the position detector and the height from the transfer substrate of the focal point of the imaging lens is set to be constant on the basis of the height detected by the height detector. With the configuration, the intensity of a radiation ray emitted to each of the areas in the transfer substrate which are sequentially scanned is maintained constant.

According to an embodiment of the present invention, there is provided a first method of manufacturing an organic light emitting element transferring a transfer layer containing an organic light emitting material onto a device substrate by using the first transfer method.

According to an embodiment of the present invention, there is provided a second method of manufacturing an organic light emitting element transferring a transfer layer containing an organic light emitting material onto a device substrate by using the second transfer method.

In the first transfer method according to the embodiment of the present invention, the transfer substrate on which the transfer layer is provided is irradiated with the radiation ray shaped in the band shape in which the short-axis width in the center portion is larger than that in the end portion in the long-axis direction. Thus, the temperature distribution in the whole surface to be irradiated becomes uniform. Therefore, the shape, quality, and the like of the transferred layer may be made uniform. When the transfer layer is made of a material containing the organic light emitting material, the organic light emitting element in which occurrence of brightness unevenness is suppressed may be manufactured.

In the second transfer method according to the embodiment of the present invention, the transfer substrate on which the transfer layer is provided is irradiated with the radiation ray shaped in the band shape in which the intensity peak value in the center portion is smaller than that in the end portion in the long-axis direction. Thus, the temperature distribution in the whole surface to be irradiated becomes uniform. Therefore, the shape, quality, and the like of the transferred layer may be made uniform. When the transfer layer is made of a material containing the organic light emitting material, the organic light emitting element in which occurrence of brightness unevenness is suppressed may be manufactured.

The transfer apparatus according to the embodiment of the present invention includes: the light source for emitting the radiation ray; the illumination lens for shaping the radiation ray to a band shape; the radiation ray splitter for splitting the radiation ray formed in the band shape by the illumination lens into a plurality of areas in a long-axis direction of the radiation ray; and the imaging lens for forming an image onto the transfer substrate from the radiation ray split by the radiation ray splitter. The imaging lens is constructed so that focus is achieved in an end portion more than in a center portion. Consequently, the short-axis width in the center portion of the radiation ray is larger than that in the end portion, and the intensity peak value in the center portion of the radiation ray is smaller than that in the end portion, so that the temperature distribution in the entire surface to be irradiated becomes uniform. Therefore, the shape, quality, and the like of the transferred layer may be made uniform.

The transfer apparatus further includes the position detector for detecting a position on the transfer substrate and the height detector for detecting a height from the transfer substrate of the imaging lens. The optical mechanism is allowed to perform a scan on the basis of the position detected by the position detector, and the height from the transfer substrate of the focal point of the imaging lens is set to be constant on the basis of the height detected by the height detector. With the configuration, the plurality of areas which are sequentially scanned are irradiated with a radiation ray having uniform intensity. Therefore, the shape, quality, and the like of the transferred layer may be formed uniformly in the larger number of areas.

Other and further objects, features and advantages of the invention will appear more fully from the following description.

### BRIEF DESCRIPTION OF THE DRAWINGS

FIG. 1 is a block diagram showing a general configuration of a transfer apparatus as an embodiment of the present invention.

FIG. 2 is a cross section showing a schematic configuration of an optical mechanism of the transfer apparatus illustrated in FIG. 1.

FIG. 3 is a perspective view showing arrangement of a position detector and a height detector in the transfer apparatus illustrated in FIG. 1.

FIG. 4 is a plan view for explaining an example of a scanning method.

FIG. 5 is a plan view for explaining an example of a scanning method.

FIG. 6 is a characteristic diagram showing the relation of minor axis width of a laser beam with respect to height H.

FIG. 7 is a diagram showing a band shape of a laser beam emitted by the transfer apparatus illustrated in FIG. 1 and an intensity distribution of the laser beam.

FIG. 8 is a cross section showing a schematic configuration of a display device manufactured by using the transfer apparatus illustrated in FIG. 1.

FIGS. 9A and 9B are cross sections showing a device substrate forming method in accordance with process order.

FIG. 10 is a cross section showing a schematic configuration of the device substrate.

FIG. 11 is a cross section showing a schematic configuration of a transfer substrate.

FIG. 12 is a cross section illustrating a laser transfer process.

FIG. 13 is a cross section illustrating a process subsequent to FIG. 12.

FIG. 14 is a cross section illustrating a process subsequent to FIG. 13.

FIG. 15 is a cross section illustrating a process subsequent to FIG. 14.

FIG. 16 is a cross section illustrating a process subsequent to FIG. 15.

FIG. 17 is a cross section illustrating a process subsequent to FIG. 16.

FIG. 18 is a diagram showing a band shape of a laser beam emitted from a transfer apparatus of a modification and an intensity distribution of the laser beam.

FIG. 19 is a diagram showing a band shape of a laser beam and an intensity distribution of the laser beam in comparative example 1.

FIG. 20 is a diagram showing a band shape of a laser beam and an intensity distribution of the laser beam in comparative examples 2 and 3.

### DETAILED DESCRIPTION OF THE PREFERRED EMBODIMENTS

Embodiments of the present invention will be described in detail hereinbelow with reference to the drawings.

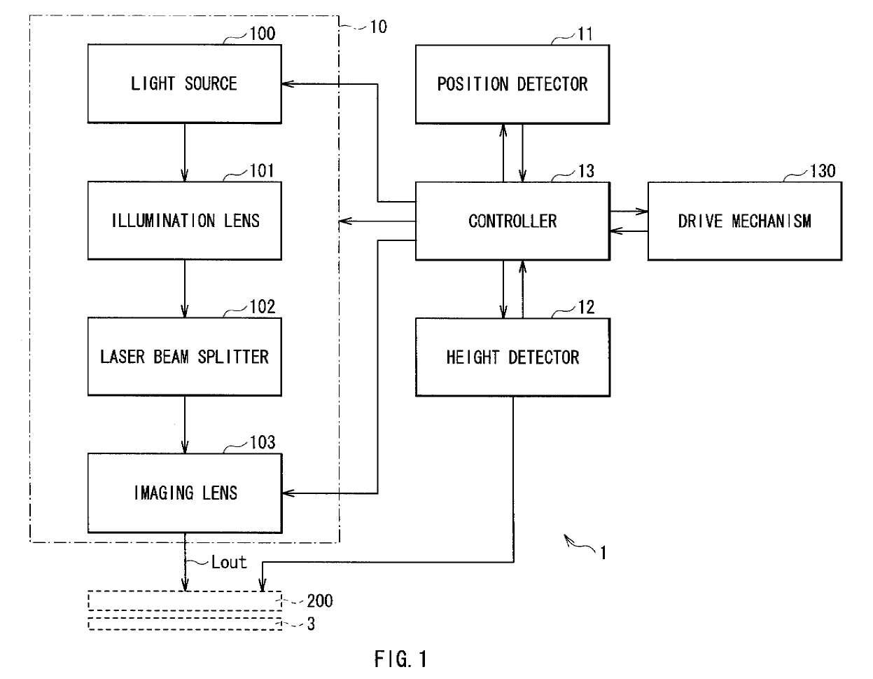

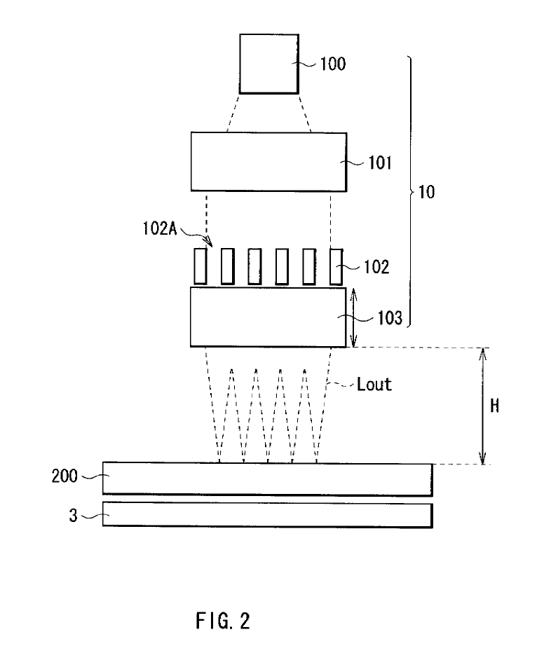

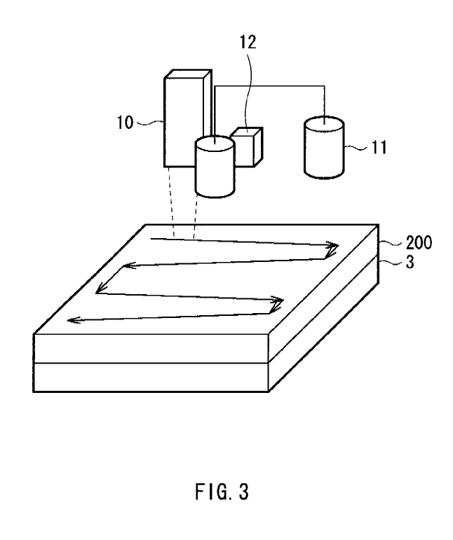

FIG. 1 shows a general configuration of a transfer apparatus 1 as an embodiment of the present invention. FIG. 2 is a cross section showing a schematic configuration of an optical mechanism 10 of the transfer apparatus 1. FIG. 3 is a perspective view showing arrangement of a position detector 11 and a height detector 12 in the transfer apparatus 1. The transfer apparatus 1 is used for, for example, transferring a pattern of an organic layer such as a light emitting layer by laser radiation in manufacture of an organic light emitting element. Since a transfer method of the present invention is embodied by the transfer apparatus of the embodiment, it will be also described below. In the following description, “center portion” refers to a center portion in the long-axis direction, and “end portion” refers to an end portion in the long-axis direction unless otherwise specified.

The transfer apparatus 1 has the optical mechanism 10, the position detector 11, the height detector 12, a controller 13, and a drive mechanism 130. In the transfer apparatus 1, the controller 13 is controlled on the basis of driving of the drive mechanism 130. While scanning the optical mechanism 10 on the basis of the operation of the position detector 11, a laser beam (Lout) is emitted to a transfer substrate 200, thereby transferring a transfer layer formed on the transfer substrate 200 onto a device substrate 3. The transfer layer on the transfer substrate 200 is constructed by containing, for example, an organic light emitting material. The device substrate 3 has, for example, a plurality of organic light emitting element formation areas (pixels).

The organic mechanism 10 has a light source 100, an illumination lens 101, a laser beam splitter 102, and a imaging lens 103. The light source 100 emits a radiation beam such as a laser beam. As the light source 100, for example, a laser diode for oscillating infrared light (having a wavelength of, for example, 808 nm) is used. The oscillation wavelength of the laser beam is determined by the material, thickness, and the like of the transfer layer on the transfer substrate 200 to be transferred. The illumination lens 101 is provided to shape the laser beam emitted from the light source 100 into a band shape.

The laser beam splitter 102 has, for example, a plurality of apertures 102A. The laser beam shaped in the band shape by the illumination lens 101 is split in correspondence with, for example, pixel transfer areas in each pixel on the device substrate 3. Therefore, the number of the apertures 102A (the splitting number) of the laser beam splitter 102 corresponds to the number of pixels which is able to be irradiated with a laser beam at once. For example, by providing five apertures 102A, a laser beam is emitted to areas corresponding to five pixels at once.

The imaging lens 103 is provided to form an image on the transfer substrate 200 using the laser beam split by the laser beam splitter 102. The imaging lens 103 is constructed so that a deviation from the focal point in the center portion is larger than that in the end portion. The imaging lens 103 is movable in a height H direction (the direction along the optical axis). On the basis of information on the height H detected by the height detector 12 which will be described later, the focal point (image forming position) is maintained at a predetermined height with respect to the transfer substrate 200.

The position detector 11 detects the position on the transfer substrate 200 on the basis of a position mark (not shown) formed on the transfer substrate 200. As the position detector 11, for example, a CCD (Charge Coupled Device) camera is used. As shown in FIG. 3, the position detector 11 is disposed in front of the optical mechanism 10 in the scan direction (travel direction) of the optical mechanism 10. Information on the position detected by the position detector 11 is input to the controller 13.

The height detector 12 typically detects the height H with respect to the transfer substrate 200, of the optical mechanism 10. As the height detector 12, for example, a laser-type displacement meter is used. Like the position detector 11, the height detector 12 is also disposed in front of the optical mechanism 10 in the scan direction. Information on the height H detected by the height detector 12 is input to the controller 13.

The controller 13 controls the optical mechanism 10 to scan the transfer substrate 200 on the basis of the information on the position detected by the position detector 11 and shifts the imaging lens 103 in the height H direction on the basis of the information on the height H detected by the height detector 12.

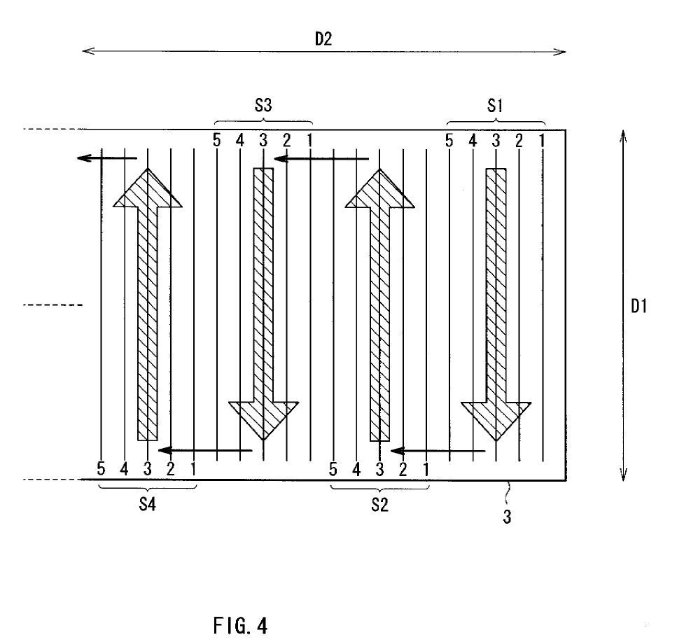

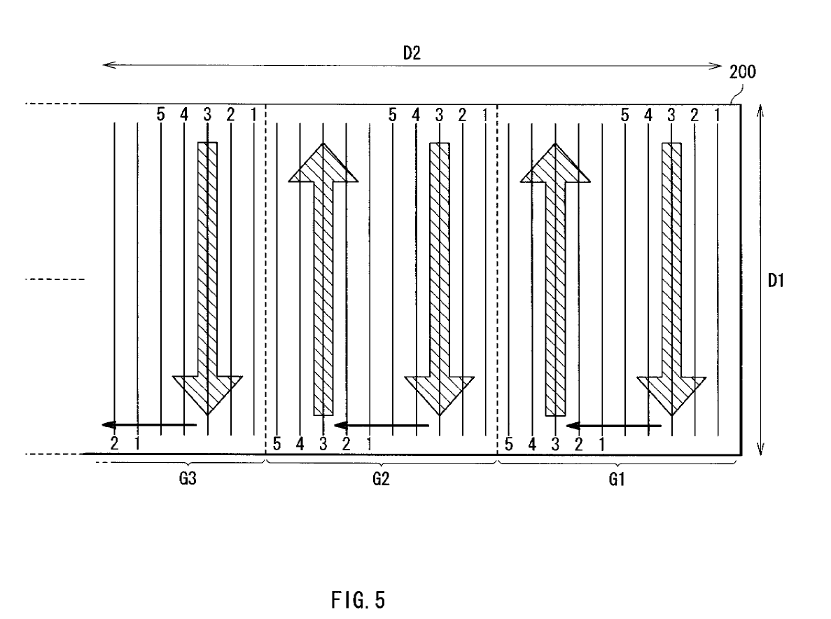

FIGS. 4 and 5 show an example of the scanning method of the optical mechanism 10 on an array of a plurality of pixels. As shown in FIG. 4, in the case where a plurality of pixels are arranged in a direction D1 on the device substrate 3, the optical mechanism 10 scans the transfer substrate 200 from one end to the other end in the direction D1. When the scan in one direction D1 is finished, the optical mechanism 10 is moved along a direction D2 orthogonal to the direction D1 to perform a scan along the direction D1 on a pixel line different from that in the previous time. A laser beam is emitted by the number corresponding to the splitting number of the laser beam splitter 102, for example, to five pixel lines S1, S2, S3, S4, and S5 by a single scan (in one direction) in a lump.

Alternatively, as shown in FIG. 5, the optical mechanisms 10 are disposed in different areas G1, G2, G3, . . . of the transfer substrate 200 and the scan as shown in FIG. 4 is performed simultaneously in the areas G1, G2, G3, . . . . In this case, the plurality of optical mechanisms 10 are controlled by the controller 13 and the scan is performed so that laser radiation areas of the optical mechanisms 10 are not overlapped each other. The optical mechanisms 10 may be disposed so that neighboring areas are scanned in opposite directions.

The action of the transfer apparatus 1 having such a configuration will now be described.

In the transfer apparatus 1, when the position detector 11 detects the position on the basis of the position mark provided on the transfer substrate 200, the information on the position is input to the controller 13. The controller 13 drives the optical mechanism 10 on the basis of the information on the position and the transfer substrate 200 is scanned. On the other hand, in the optical mechanism 10, when the light source 100 is driven by the control of the controller 13, a laser beam is oscillated and shaped in a band shape by the illumination lens 101. The laser beam shaped in the band shape enters the laser beam splitter 102 and is split to pixel units by the apertures 102A formed in the laser beam splitter 102. The band-shaped laser beam split as described above is deflected by the imaging lens 103 and an image is formed on the transfer substrate 200. The transfer layer provided on the transfer substrate 200 is transferred to the device substrate 3 to which an object is transferred.

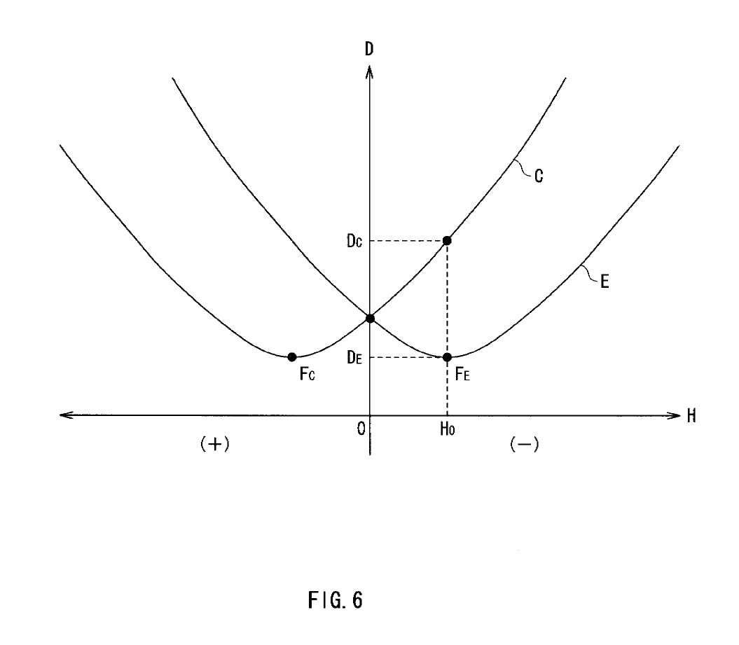

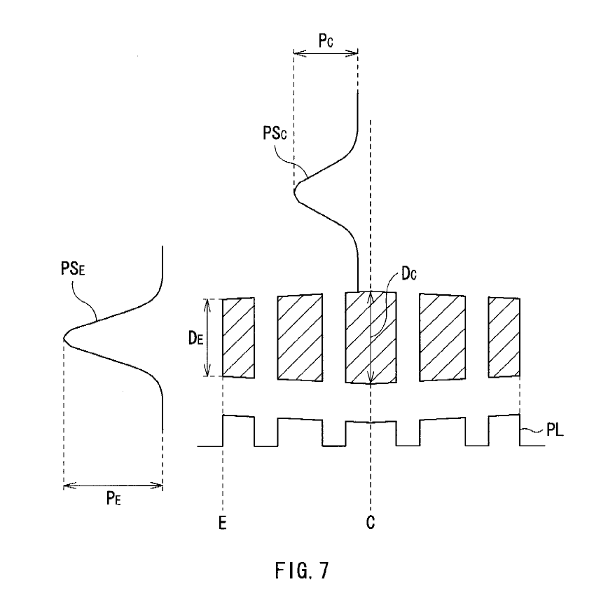

Referring to FIGS. 6 and 7, concrete operations of the imaging lens 103 and the height detector 12 in the optical mechanism 10 will be described. FIG. 6 shows the relation between the height H from the transfer substrate 200, of the imaging lens 103 and the width D in the short-axis direction (hereinbelow, simply called short-axis width) of a laser beam that forms an image on the transfer substrate 200. FIG. 7 shows a band shape of a laser beam that forms an image on the transfer substrate 200 and an intensity distribution of the laser beam.

As shown in FIG. 6, when a laser beam enters the imaging lens 103, a deviation occurs from the focal point (image formation position) depending on the height H. Consequently, the short-axis width D changes in correspondence with the deviation from the focal point. In the imaging lens 103, the height of a focal point F_{C} in a center portion C and that of a focal point F_{E} in an end portion E are different from each other due to the aberration of the lens. Therefore, it is set so that the deviation from the focal point F_{C} in the center portion C becomes larger than that from the focal point F_{E} in the end portion E. For example, the height H when a deviation from the focal point in the center portion C and that from the focal point in the end portion E are equal to each other (when the short-axis width in the center portion C and that in the end portion E are equal to each other) is set to 0 (zero). By shifting the imaging lens 103 so that the height H becomes smaller than 0, an image is formed on the transfer substrate 200 by using the band-shaped laser beam having the intensity distribution as shown in FIG. 7. The − direction in FIG. 6 shows the direction in which the height H decreases, and the + direction shows the direction in which the height H increases.

Since it is constructed so that the deviation from the focal point F_{C} in the center portion C becomes larger than that from the focal point F_{E} in the end portion E in the imaging lens 103, in the band shape of the split laser beam, a short-axis width D_{C} in the center portion C becomes larger than a short-axis width D_{E} in the end portion E. The intensity distribution in the short-axis direction in the center portion C and that in the end portion E are different from each other. A peak value P_{C} of an intensity distribution PS_{C} in the center portion C becomes smaller than a peak value P_{E} of an intensity distribution PS_{E} in the end portion E. In the intensity distribution PL in the long-axis direction, the intensity in the end portion E is higher than that in the center portion C.

On the other hand, the height detector 12 detects the height H accompanying the sequential scan of the optical mechanism 10. When the information on the height H is input to the controller 13, the controller 13 pre-stores, as reference height H0, the height H at which an image in the band shape having the intensity distribution as shown in FIG. 7 is formed. By comparing the reference height H0 and the height H detected by the height detector 12 with each other, the imaging lens 103 is shifted so that the height H from the transfer substrate 200 of the imaging lens 103 typically becomes the reference height H0.

Therefore, the height H from the transfer substrate 200 of the imaging lens 103 that scans the transfer substrate 200 is detected by the height detector 12. When the information on the height H is input to the controller 13, the imaging lens 103 is shifted in the height H direction so that the height of the focal point becomes typically constant relative to the transfer substrate 200.

As described above, in the transfer apparatus 1, the imaging lens 103 of the optical mechanism 10 is constructed so that the deviation from the focal point F_{C} in the center portion C becomes larger than that from the focal point F_{E} in the end portion E. Consequently, in the band shape of the laser beam which is split into the plurality of pieces, the short-axis width in the center portion C becomes larger than that in the end portion E. In the intensity distribution in the short-axis direction, the intensity peak value P_{C} in the center portion C becomes smaller than the intensity peak value P_{E} in the end portion E. Generally, when a laser beam is emitted to the areas corresponding to the plurality of pixels, heat is accumulated and temperature rises in the center portion C more than that in the end portion E because of the lens configuration of the imaging lens 103, the arrangement of pixels, and the like. In the embodiment, in the band shape of the laser beam, the short-axis width in the center portion C is larger than that in the end portion E, and the intensity peak value P_{C} in the short-axis direction in the center portion C is smaller than the intensity peak value P_{E} in the short-axis direction. Consequently, the energy density of the laser beam in the center portion C becomes low, and the temperature rise in the center portion C is lessened. Therefore, occurrence of the temperature difference between the center portion C and the end portion E is suppressed, and the temperature distribution in an entire irradiation surface A is uniformed. Thus, it is possible to uniform the shape and quality of the layer to be transferred.

While detecting the position of the transfer substrate 200 by the position detector 11, the controller 13 performs the scanning of the optical mechanism 10. Therefore, a positional deviation from the transfer substrate 200 of the optical mechanism 10 is prevented, and a laser beam is irradiated to a desired area with high precision.

Further, the height detector 12 detects the height H from the transfer substrate 200 of the imaging lens 103, and the focal point height of the imaging lens 103 is set to be typically constant on the basis of the height H. Therefore, the intensity of a radiation beam emitted is kept typically constant in each of the areas in the transfer substrate 200 sequentially scanned by the optical mechanism 10. A laser beam is emitted with uniform intensity in the scan direction of a plurality of pixels sequentially scanned.

In the optical mechanism 10, the band-shaped laser beam is split into pixel units by the laser beam splitter 102, so that an image is transferred to a plurality of pixels in a lump by single laser radiation. By providing a larger number of apertures 102A in the laser beam splitter 102, a laser beam is emitted to a larger number of pixels in a lump. Generally, when the number of pixels to be irradiated with a laser beam in a lump is increased or the arrangement density of pixels is increased, heat is accumulated in the center portion C more than the end portion E, and the temperature distribution becomes nonuniform. In the embodiment, the intensity distribution of a laser beam is optimized. Consequently, even in the case where the number of pixels irradiated with a laser beam in a lump is increased or the arrangement density of pixels is increased, without complicating the optical mechanism, a layer to be transferred is formed in uniform shape and quality.

An application example of such a transfer apparatus 1 will now be described. The transfer apparatus 1 may be used for, for example, manufacture of the display device 2 having an organic light emitting element.

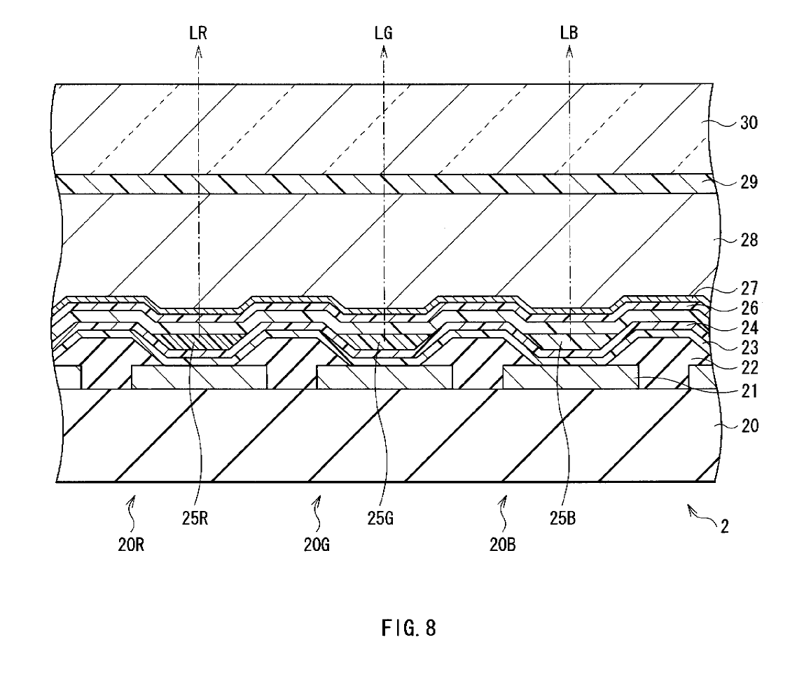

First, with reference to FIG. 8, the configuration of the display device 2 will be described. FIG. 8 is a cross section showing a schematic configuration of the display device 2. The display device 2 is used as a thin-type organic light emitting color display device or the like. For example, on a drive substrate 20, a red organic light emitting element 20R for generating red light, a green organic light emitting element 20G for generating green light, and a blue organic light emitting element 20B for generating blue light are repeatedly disposed in order, thereby forming a matrix as a whole. The red organic light emitting elements 20R, the green organic light emitting elements 20G, and the blue organic light emitting elements 20B are covered with a protection film 28 and sealed by a sealing substrate 30 with an adhesive layer 29 in between. The display device 2 is a display device of a top-face light emitting type in which the red organic light emitting element 20R, the green organic light emitting element 20G, and the blue organic light emitting element 20B emit light LR, LG, and LB of three colors, respectively, from the top face of the sealing substrate 30.

The drive substrate 20 is constructed by stacking, for example, switching elements (not shown) such as a TFT (Thin Film Transistor) element, wirings (not shown) such as a gate line and a source line connected to the switching elements, a planarizing insulating layer (not shown) for planarizing the elements and wirings, and the like. Contact holes are formed in the planarizing insulating layer and are electrically connected to the TFT elements and the red organic light emitting element 20R, the green organic light emitting element 20G, and the blue organic light emitting element 20B on the drive substrate 10.

In the red organic light emitting element 20R, for example, a first electrode 21, an insulating film 22, a hole injection layer 23, a hole transport layer 24, a red light emitting layer 25R, an electronic transport layer 26, and a second electrode 27 are stacked in order from the side of the drive substrate 20. In the green organic light emitting element 20G, the first electrode 21, the insulating film 22, the hole injection layer 23, the hole transport layer 24, a green light emitting layer 25G, the electronic transport layer 26, and the second electrode 27 are stacked in order from the side of the drive substrate 20. In the blue organic light emitting element 20B, the first electrode 21, the insulating film 22, the hole injection layer 23, the hole transport layer 24, the blue light emitting layer 25B, the electronic transport layer 26, and the second electrode 27 are stacked in order from the side of the drive substrate 20.

The first electrode 21 functions, for example, as an anode electrode and is made of a metal such as aluminum (Al), chromium (Cr), molybdenum (Mo), silver (Ag) or the like or an alloy of any of the metals. The first electrode 21 may have a single-layer structure or a laminated-layer structure. In the case of an under-face light emitting type, for example, the first electrode 21 may be constructed by a transparent electrode made of ITO, IZO (indium zinc oxide), or the like. The first electrode 21 has a thickness of, for example, 50 nm to 1000 nm.

The insulating film 22 assures electric insulation among the red organic light emitting element 20R, the green organic light emitting element 20G, and the blue organic light emitting element 20B. The insulating film 22 is made of, for example, a photosensitive resin such as polybenzoxazole, polyimide, acryl, or the like and has a thickness of, for example, 2.0 μm. In the insulating film 22, apertures are provided in correspondence with light emitting areas.

The hole injection layer 23, the hole transport layer 24, and the electronic transport layer 26 are layers shared by the red organic light emitting element 20R, the green organic light emitting element 20G, and the blue organic light emitting element 20B. The layers are provided as necessary and may have different configurations according to light emission colors.

The hole injection layer 23 is a buffer layer for increasing the hole injection efficiency and for preventing leakage. The hole injection layer 23 has, for example, a thickness of 5 nm to 300 nm and is, for example, 25 nm thick. The hole injection layer 23 is made of 4,4′,4″-tris(3-methylphenylphenylamino)triphenylamine (m-MTDATA) or 4,4′,4″-tris(2-naphtylphenylamino)triphenylamine (2-TNANA).

The hole transport layer 24 is provided to increase the hole transport efficiency to the red light emitting layer 25R, the green light emitting layer 25G, and the blue light emitting layer 25B. The hole transport layer 24 has, for example, a thickness of 5 nm to 300 nm and is, for example, 30 nm thick. The hole transport layer is made of 4,4′-bis(N-1-naphthyl-N-phenylamino)biphenyl (α-NPD).

When an electric field is applied to the red light emitting layer 25R, the green light emitting layer 25G, and the blue light emitting layer 25B, electrons and holes are recombined. The layers function as light emitting layers that emit light.

The red light emitting layer 25R contains at least one of a red light emitting material, a hole transport material, an electron transport material, and a positive/negative charge transport material. The red light emitting layer 25R has a thickness of, for example, 10 to 100 nm. The red light emitting material may be fluorescent or phosphorus and is obtained by, for example, mixing ADN (di-2-naphthyl)anthracene) with 30 weight % of 2,6-bis[(4′-methoxy-diphenylamino)styryl]-1,5-dicyanonaphthalene (BSN).

The green light emitting layer 25G contains at least one of a green light emitting material, a hole transport material, an electron transport material, and a positive/negative charge transport material. The green light emitting layer 25G has a thickness of, for example, 10 to 100 nm. The green light emitting material may be fluorescent or phosphorus and is obtained by, for example, mixing ADN with 5 weight % of Coumarin6.

The blue light emitting layer 25B contains at least one of a blue light emitting material, a hole transport material, an electron transport material, and a positive/negative charge transport material. The blue light emitting layer 25B has a thickness of, for example, 10 to 100 nm. The blue light emitting material may be fluorescent or phosphorus and is obtained by, for example, mixing

ADN with 2.5 weight % of 4,4′-bis[2-{4-(N,N-diphenylamino)phenyl}yinyl]biphenyl (DPAVBi).

The electronic transport layer 26 is provided to increase the electronic transport efficiency and is made of, for example, 8-hydroxyquinoline aluminum (Alq3) and has a thickness of, for example, 20 nm. An electronic injection layer made of, for example, LiF, Li₂O, or the like may be provided to increase the electron injection efficiency between the electronic transport layer 26 and the second electrode 27.

The second electrode 27 functions as, for example, a cathode electrode, is a transparent electrode or a semi-transparent electrode, and has a thickness of, for example, 5 nm to 50 nm. In the case of the top face light emission type, preferably, the second electrode 27 is made of a material having a small work function so that electrons are efficiently injected to the organic layer. The second electrode is made of, for example, a simple substance of metallic element such as magnesium (Mg) or silver (Ag) or an alloy of such a metallic element. Preferably, the second electrode 27 is formed by a method using small film formation particle energy such as evaporation.

The protection film 28 is provided to prevent entry of moisture, oxygen, and the like to the red organic light emitting element 20R, the green organic light emitting element 20G, and the blue organic light emitting element 20B. The protection film 28 is made of a material having low permeability and low water absorption rate and has a sufficient film thickness. The protection film 28 is made of a material having high permeability of light generated by the red light emitting layer 25R, the green light emitting layer 25G, and the blue light emitting layer 25B and having a light transmission of, for example 80% or higher. Such a protection film 28 has a thickness of, for example, about 2 μm to 3 μm and is made of an inorganic amorphous insulating material. Concretely, amorphous silicon (α-Si), amorphous silicon carbide (α-SiC), amorphous silicon nitride (α-Si₁₋ₓNₓ), and amorphous carbon (α-C) are preferable. Those inorganic amorphous insulating materials do not form grains and have low permeability, so that an excellent protection film is formed by using any of the materials. The protection film 28 may be made of a transparent conductive material such as ITO or IXO.

The adhesive layer 29 is made of, for example, a thermoset resin, an ultraviolet curing resin, or the like.

The sealing substrate 30 is made of a material such as transparent glass for the light generated by the red light emitting layer 25R, the green light emitting layer 25G, and the blue light emitting layer 25B.

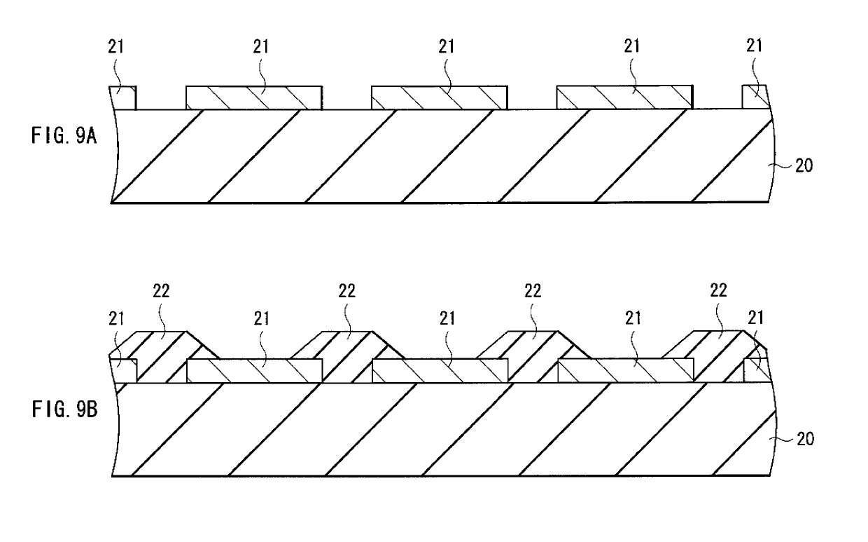

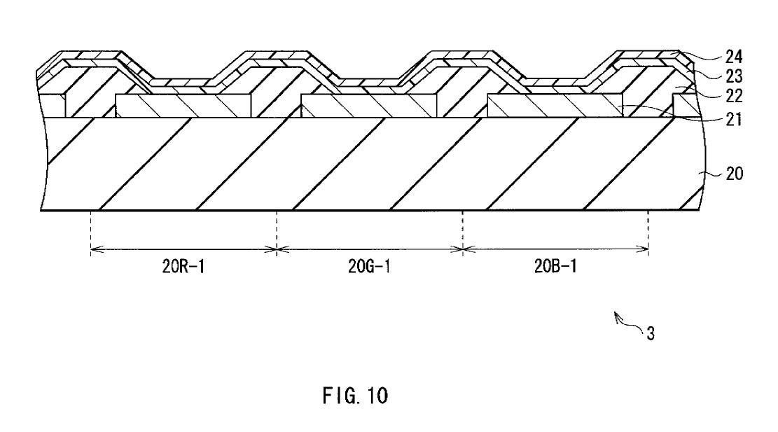

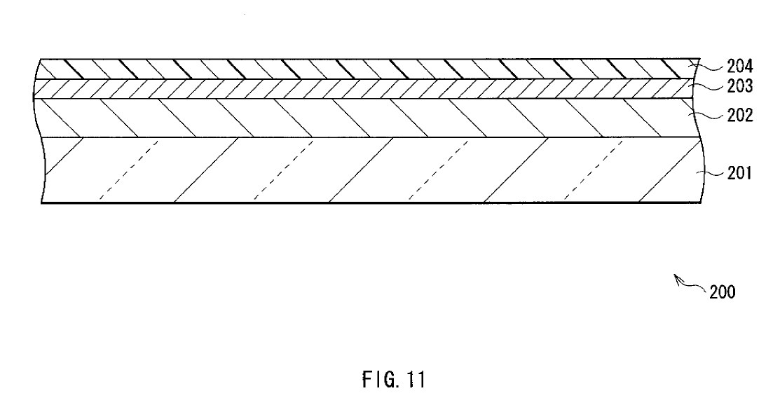

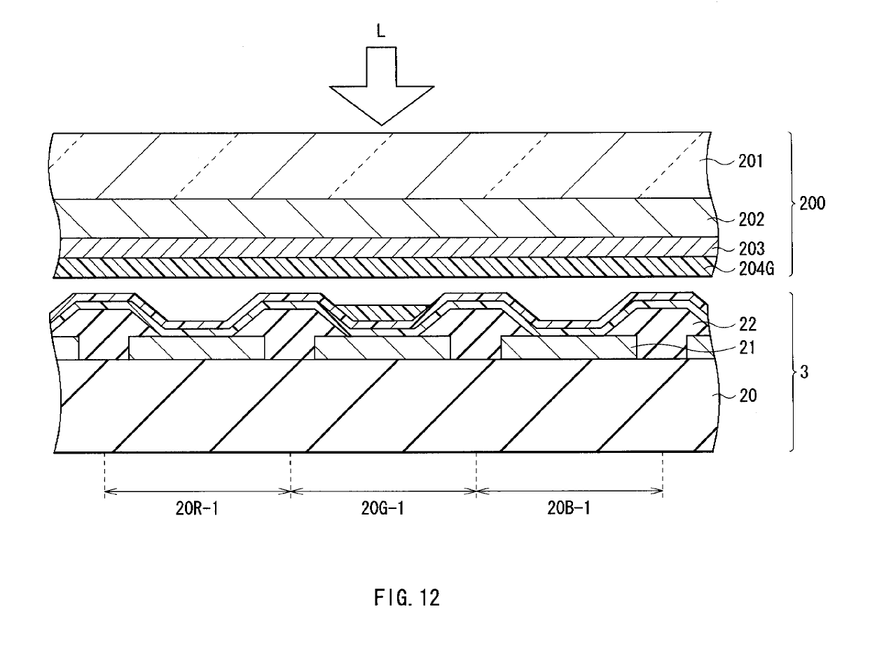

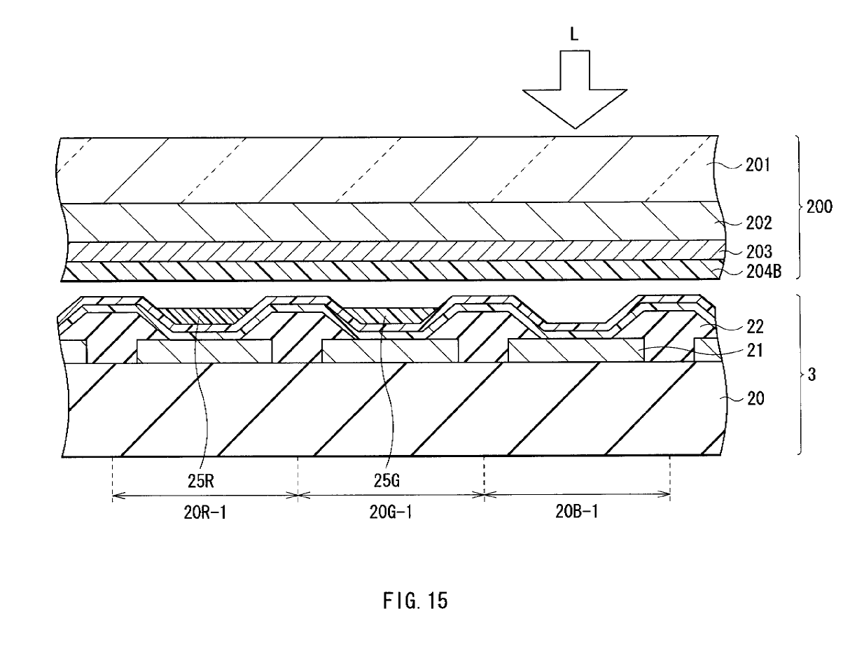

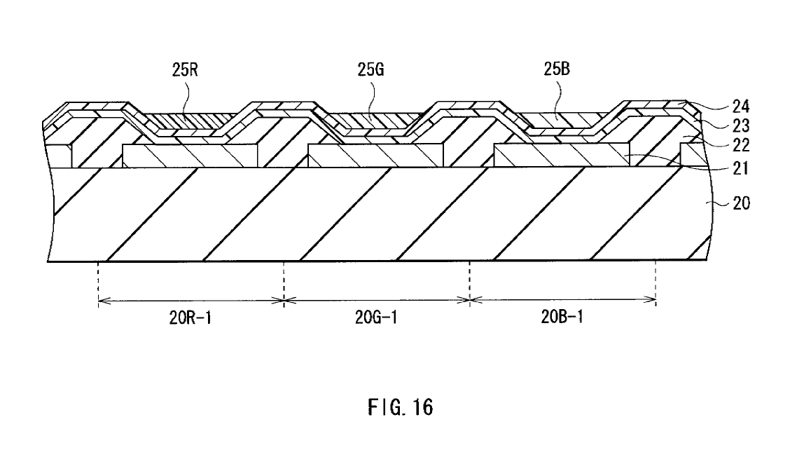

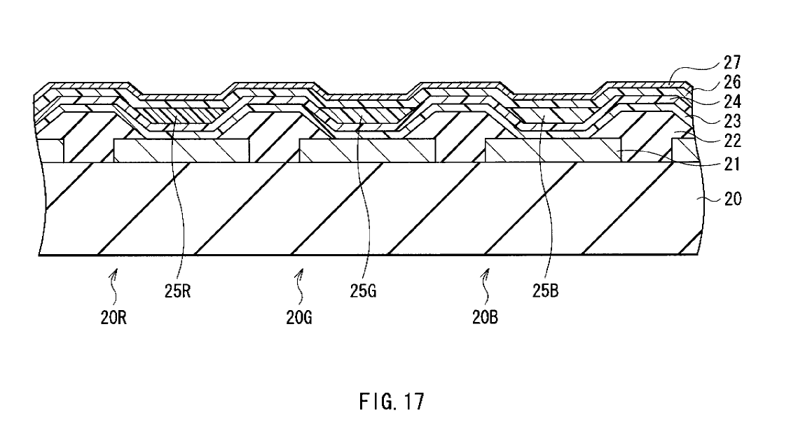

With reference to FIGS. 9A and 9B to FIG. 17, the method of manufacturing the display device 2 will now be described. FIGS. 9A and 9B and FIG. 10 are diagrams showing the processes of forming the device substrate 3 in process order. FIG. 11 is a diagram showing a sectional configuration of the transfer substrate 200. FIGS. 12 to 15 are diagrams showing a laser transfer process in process order. FIGS. 16 and 17 are diagrams showing processes subsequent to FIG. 15.

First, the device substrate 3 is formed as follows. As shown in FIG. 9A, the first electrode 21 is formed on the drive substrate 20 by sputtering or the like, patterned by photolithography or the like, and shaped into a predetermined shape by etching. Since not-shown TFT elements and wirings such as a gate line and a source line are disposed on the drive substrate 20, a planarization insulating film covering those elements and wirings to make the surface planarized is formed. A contact hole is formed in the planarization insulting film to make the drive substrate 20 and the first electrode 21 electrically connected to each other.

Subsequently, as shown in FIG. 9B, a photosensitive resin is coated on the entire surface of the drive substrate 20 by, for example, spin coating and shaped into a shape in which apertures are formed in portions corresponding to the first electrodes 21 by, for example, photolithography. After that, the resultant is fired to form the insulating film 22.

Subsequently, as shown in FIG. 10, by sequentially forming the hole injection layer 23 and the hole transport layer 24 by, for example, evaporation so as to cover the first electrode 21 and the insulating film 22 formed, the device substrate 3 having a red device formation area 20R−1, a green device formation area 20G−1, and a blue device formation area 20B−1 is formed.

Meanwhile, the transfer substrate 200 is formed as follows. As shown in FIG. 11, on a substrate 201 such as a transparent substrate made of glass or the like, a light absorption layer 202 is formed in sufficient thickness by, for example, sputtering. Subsequently, a protection layer 203 is formed on the light absorption layer 202 by, for example, CVD (Chemical Vapor Deposition), thereby forming the transfer substrate 200. The light absorption layer 202 is made of a material that absorbs light energy and converts it to thermal energy, for example, a metal material having high absorptivity such as chromium (Cr), molybdenum (Mo), titanium (Ti), or an alloy containing any of them. The protection layer 203 is made of an amorphous silicon such as SiNx and prevents oxidation of the light absorption layer 202. A transfer layer 204 to be transferred onto the device substrate 3 is formed on the side of the protection layer 203 of the transfer substrate 200. As the transfer layer 204, a red transfer layer 204R containing a red light emitting material, a green transfer layer 204G containing a green light emitting material, and a blue transfer layer 204B containing a blue light emitting material are formed by, for example, vacuum evaporation.

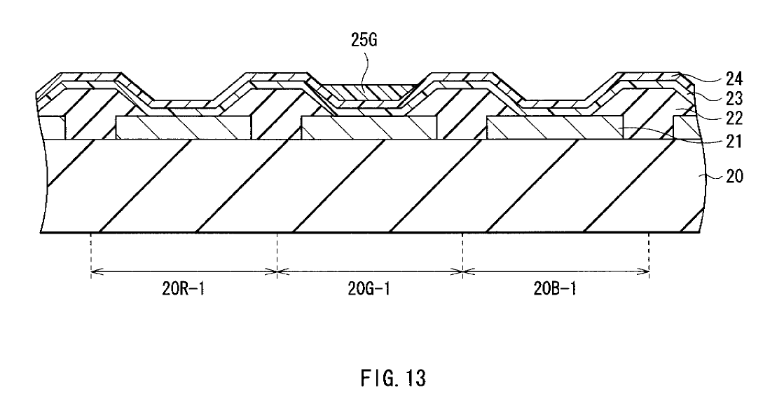

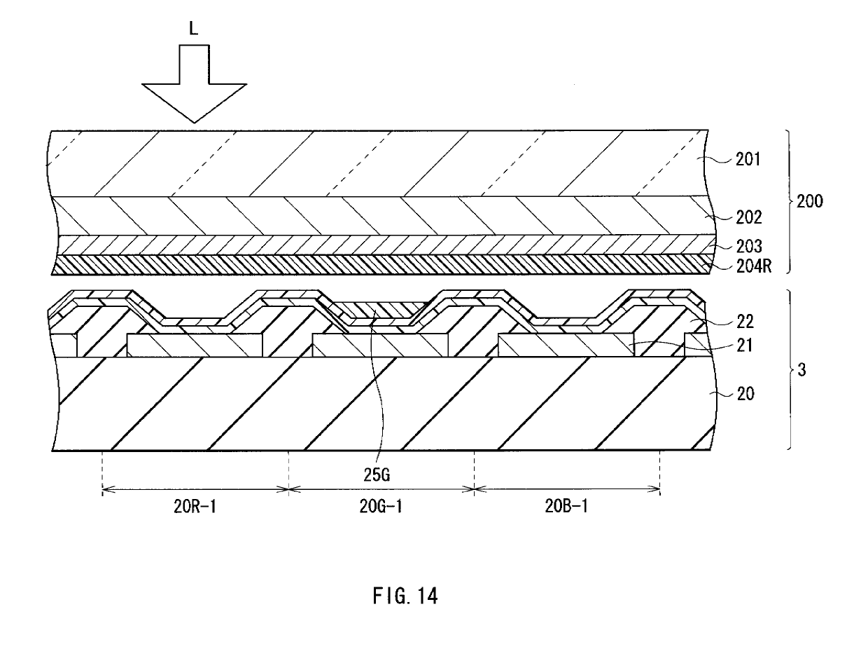

Subsequently, as shown in FIG. 12, the transfer layer 204 formed on the transfer substrate 200 is transferred onto the device substrate 3 formed. As the transfer layer 204, first, the green transfer layer 204G containing a green light emitting material is formed and disposed so as to face the device substrate 3. A laser beam L is emitted from the side of the transfer substrate 200 to the green device formation area 20G−1. At this time, using the transfer apparatus 1 of the embodiment, the laser beam is emitted to a plurality of green device formation areas 20G−1 on the device substrate 3. As a result, as shown in FIG. 13, the green light emitting layer 25G as a transferred layer is formed in the green device formation area 20G−1. Subsequently, the red transfer layer 204R and the blue transfer layer 204B are transferred in order in a manner similar to the above as shown in FIGS. 14 and 15, thereby forming the red light emitting layer 25R, the green light emitting layer 25G, and the blue light emitting layer 25B in the red device formation area 20R−1, the green device formation area 20G−1, and the blue device formation area 20B−1, respectively, as shown in FIG. 16.

Subsequently, as shown in FIG. 17, the electron transport layer 26 and the second electrode 27 are formed in order by, for example, vacuum deposition. In such a manner, the red organic light emitting element 20R, the green organic light emitting element 20G, and the blue organic light emitting element 20B are formed on the drive substrate 20.

After formation of the red organic light emitting element 20R, the green organic light emitting element 20G, and the blue organic light emitting element 20B, the protection film 28 is formed on these elements. A preferable method at this time is a film forming method using film formation particle energy small enough to exert no influence on the substrate, for example, evaporation or CVD. It is also preferable to continuously form the protection film 28 and the second electrode 27 without exposing the second electrode 27 to the atmosphere for the reason that degradation in the red organic light emitting element 20R, the green organic light emitting element 20G, and the blue organic light emitting element 20B caused by moisture and oxygen in the atmosphere may be suppressed. Further, it is preferable to set the film formation temperature of the protection film 28 to ordinary temperature in order to prevent deterioration in brightness of the red organic light emitting element 20R, the green organic light emitting element 20G, and the blue organic light emitting element 20B. It is desirable to form the film under condition that stress on the film becomes the minimum in order to prevent the protection film 28 from being peeled off.

Finally, the adhesive layer 29 is formed on the protection film 28, and the sealing substrate 30 is adhered to the protection film 28 with the adhesive layer 29 in between. As a result, the display device 2 shown in FIG. 8 is completed.

In the display device 2 manufactured as described above, the red light emitting layer 25R, the green light emitting layer 25G, and the blue light emitting layer 25B are formed by being transferred by the transfer apparatus 1 of the embodiment in the red organic light emitting element 20R, the green organic light emitting element 20G, and the blue organic light emitting element 20B, respectively, formed on the drive substrate 20 so that the shapes and qualities are uniform. Therefore, brightness unevenness in the display device 2 as a whole is suppressed, and uniform surface emission is realized.

### Modification

A modification of the transfer apparatus 1 of the embodiment will now be described.

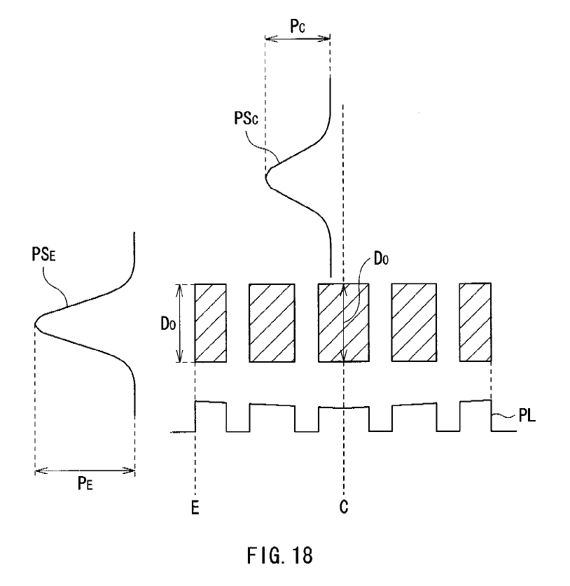

FIG. 18 shows the band shape and an intensity distribution of a laser beam formed on the transfer substrate 200 by using the transfer apparatus of the modification. The modification has a configuration similar to that of the transfer apparatus 1 except for the laser beam splitter. To be concrete, light transmittance in the center portion of the laser beam splitter is set to be lower than that in the end portion (not shown). In such a configuration, for example, it is sufficient to provide a film that reflects light or a film that absorbs light in an aperture in the center portion. By constructing the laser beam splitter so that the light transmittance in the center portion becomes lower than that in the end portion, the intensity peak value in the center portion becomes smaller than that in the end portion. Therefore, as shown in FIG. 18, a short-axis width D₀ of the band shape of a laser beam is the same in the center portion C and the end portion E. On the other hand, an intensity peak value P_{C} of an intensity distribution PS_{C} in the center portion in the short-axis direction is smaller than an intensity peak value P_{E} in the intensity distribution PS_{E} in the end portion. An intensity distribution PL in the long-axis direction is low in the center portion and high in the end portion. Therefore, occurrence of the temperature difference between the center portion and the end portion of the band shape of a laser beam is suppressed, and the shape and quality of a transferred layer may be made uniform.

### EXAMPLES

Next, examples of the display device 2 of the embodiment will be described.

As example 1, brightness unevenness of a display device manufactured using a band-shaped laser beam having an intensity distribution as shown in FIG. 7 was evaluated. When the height H from the transfer substrate 200 of the imaging lens 103 was set to −50 μm, the ratio (D_{C}/D_{E}) between the short-axis width D_{C} in the center portion C and the short-axis width D_{E} in the end portion E became 1.4, and the ratio (P_{C}/P_{E}) between the intensity peak value P_{C} in the short-axis direction in the center portion C and the intensity peak value P_{E} in the short-axis direction in the end portion E became 0.7. The wavelength of a laser beam was set to 808 nm, and scan speed was set to 250 mm/sec. The state where the short-axis width in the center portion C and that in the end portion E are equal to each other is expressed as 0. The direction of decreasing the height H from the state is expressed in the − (minus) sign, and the direction of increasing the height H is expressed in the + (plus) sign.

In example 2, the brightness unevenness was evaluated in a manner similar to the example 1 except that when the height H was set to −25 μm, the short-axis width ratio (D_{C}/D_{E}) became 1.3 and the intensity peak ratio P_{C}/P_{E} became 0.8. Table 1 shows results of the examples 1 and 2.

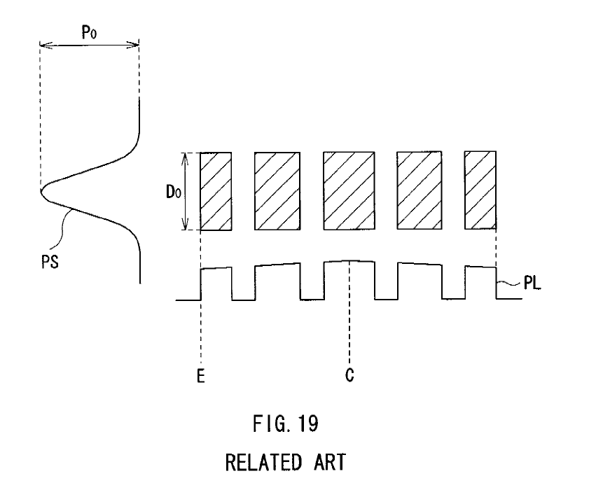

As comparative example 1 of the examples 1 and 2, brightness unevenness of a display device of the related art manufactured using a band-shaped laser beam shown in FIG. 19 was evaluated. In the comparative example 1, the height H was set to 0, that is, the short-axis width D₀ between the center portion C and the end portion E was set to be constant (the short-axis width ratio D_{C}/D_{E} was 1.0). In this case, as described above, with the configuration of the imaging lens and the transmittance distribution of the lens used for the imaging lens, the intensity peak value in the center portion is higher than that in the end portion, so that the intensity peak ratio P_{C}/P_{E} became 1.2. The other conditions were set in a manner similar to the example 1.

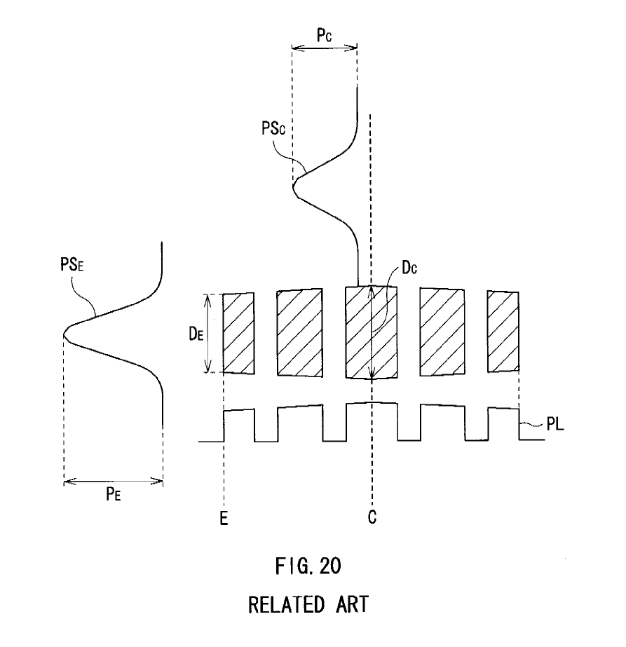

As comparative examples 2 and 3 of the examples 1 and 2, rightness unevenness of a display device manufactured using a band-shaped laser beam shown in FIG. 20 was evaluated. In the comparative example 2, the height H was set to +25 μm, the short-axis width ratio D_{C}/D_{E} was set to 0.8, and the intensity peak ratio P_{C}/P_{E} was set to 1.4. In the comparative example 3, the height H was set to +50 μm, the short-axis width ratio D_{C}/D_{E} was set to 0.7, and the intensity peak ratio P_{C}/P_{E} was set to 1.4. The other conditions were set in a manner similar to the example 1. The results of the comparative examples 1 to 3 are shown in Table 1 together with the results of the examples 1 and 2.

TABLE 1

| | | Short-axis | Intensity | |
|---|---|---|---|---|
| | Height | width ratio | peak ratio | Display |
| | H (μm) | (D_{C}/D_{E}) | (P_{C}/P_{E}) | result |
| Example 1 | −50 | 1.4 | 0.7 | Excellent |
| Example 2 | −25 | 1.3 | 0.8 | Excellent |
| Comparative | 0 | 1.0 | 1.2 | Poor |
| example 1 | | | | |
| Comparative | +25 | 0.8 | 1.4 | Very poor |
| example 2 | | | | |
| Comparative | +50 | 0.7 | 1.4 | Very poor |
| example 3 | | | | |

As shown in Table 1, in the examples 1 and 2, the brightness unevenness is sufficiently suppressed, and the display result is excellent. In contrast, the display result is poor in the comparative example 1 and is very poor in the comparative examples 2 and 3. The results show that, by using a band-shaped laser beam in which the short-axis width D_{C} in the center portion C is larger than the short-axis width D_{E} in the end portion E and the intensity peak value in the short-axis direction in the center portion C is smaller than that in the end portion E when the height H is set larger than 0, the shape and quality of the light emitting layer as a transferred layer become uniform. Thus, occurrence of brightness unevenness in the whole display device is suppressed.

The present invention has been described by the embodiment and examples. The invention, however, is not limited to the foregoing embodiment and the like but can be variously modified. For example, although the case of transferring a layer by emitting a laser beam has been described in the foregoing embodiment, another radiation beam such as a beam from a lamp may be emitted.

In the foregoing embodiment and the like, the case where the transfer substrate 200 is scanned by moving the optical mechanism 10 over the transfer substrate 200 has been described. However, the invention is not limited to the case. For example, by moving a stage (not shown) or the like on which the transfer substrate 200 is mounted, the transfer substrate 200 may be scanned by the optical mechanism 10.

Although the case where the display device 2 is of the top surface emission type has been described in the embodiment and the like, the invention is not limited to the case. The display device 2 may be of a transmission type or a under-face emission type. Although the case of using the second electrode 27 as a cathode electrode has been described, the second electrode 27 may be used as an anode electrode. For example, in the case of the transmission type, when the second electrode is used as an anode electrode, the second electrode is made of a conductive material having high reflectance. When the second electrode is used as a cathode electrode, the second electrode is made of a conducive material having small work function and high reflectance.

Although the case where the number of apertures 102A in the laser beam splitter 102 is five has been described in the foregoing embodiment and the like, the number is not limited to five. When the number is two or larger, the effects of the present invention are achieved. Preferably, the number of apertures 102A is determined according to the number of pixels or size of the whole display area. For example, the standard of a general display and television is often multiples of 8 or 10 such as 1,024×768 and 1,920×1,080. In the case of manufacturing a display device having such number of pixels, preferably, apertures 102A of the number corresponding to, for example, multiples of 8 or 10 are provided.

Although the scan speed is set to 250 mm/sec in the foregoing embodiment and the like, the invention is not limited to the scan speed. For example, a scan may be performed at about 50 to 1,000 mm/sec depending on necessary energy density and the position precision of the transfer film with respect to the pixel array.

In the embodiment and the like, the height in the state where the short-axis width in the center portion C and that in the end portion E are equal to each other is expressed as 0. The direction of decreasing the height H from the state is expressed in the − (minus) sign, and the direction of increasing the height H is expressed in the + (plus) sign. The height H is set by shifting the imaging lens in the − direction so as to decrease a deviation from the focal point in the end portion E more than that in the center portion C. However, the invention is not limited to the embodiment and the like. For example, depending on the configuration of the imaging lens, the height H may be set by shifting the imaging lens in the + direction. By the operation, a deviation from the focal point in the end portion E may be made smaller than that in the center portion C.

The invention is not limited to the materials and thicknesses of the layers, the film forming methods, film forming conditions, the irradiation parameters of the laser beam L, and the like described in the foregoing embodiment and the like. Other materials, other thicknesses, other film forming methods, other film forming conditions, and other irradiation parameters may be used.

Although the configurations of the red organic light emitting element 20R, the green organic light emitting element 20G, and the blue organic light emitting element 20B have been concretely described in the foregoing embodiment and the like, it is unnecessary to all of the layers, or another layer may be further provided. For example, a thin film for injecting holes made of chromium trioxide (Cr₂O₃), ITO, or the like may be provided between the first electrode 21 and the hole injection layer 23.

Obviously many modifications and variations of the present invention are possible in the light of the above teachings. It is therefore to be understood that within the scope of the appended claims the invention may be practiced otherwise than as specifically described.

What is claimed is:

1. A transfer method comprising the steps of:
disposing a transfer substrate and an acceptor substrate so as to face each other, a transfer layer being provided on the transfer substrate, a plurality of areas being arranged in the acceptor substrate; and
transferring the transfer layer to the plurality of areas by emitting a radiation ray from the transfer substrate side,
wherein,
the radiation ray is shaped in a band shape, and
an intensity peak value in a center portion in a long-axis direction of the radiation ray is set to be smaller than that in an end portion.

2. The transfer method according to claim 1, wherein the radiation ray is emitted via a mask having apertures provided in correspondence with the plurality of areas.

3. A transfer apparatus for transferring a transfer layer formed on a transfer substrate to an acceptor substrate by irradiating the transfer substrate with a radiation ray, the apparatus comprising an optical mechanism for emitting the radiation ray to the transfer substrate, the optical mechanism including:
a light source for emitting the radiation ray;
an illumination lens for shaping the radiation ray to a band shape;
a radiation ray splitter for splitting the radiation ray formed in the band shape by the illumination lens into a plurality of areas in a long-axis direction of the radiation ray; and
an imaging lens for forming an image onto the transfer substrate from the radiation ray split by the radiation ray splitter,
wherein,
the imaging lens is constructed so that a deviation from a focal point in a center portion is larger than that in an end portion.

4. The transfer apparatus according to claim 3, further comprising a position detector for detecting a position on the transfer substrate, the optical mechanism scanning each of the areas in the transfer substrate on the basis of the position detected by the position detector.

5. The transfer apparatus according to claim 4, further comprising a height detector for detecting a height from the transfer substrate of the imaging lens,
wherein,
the imaging lens is movable along the height direction, and
the height from the transfer substrate of the focal point is set to be constant on the basis of the height detected by the height detector.

6. The transfer apparatus according to claim 4, wherein:
the acceptor substrate is obtained by arranging a plurality of pixels, and
the optical mechanism scans the acceptor substrate along the pixel arrangement direction.

7. The transfer apparatus according to claim 4, wherein a plurality of the optical mechanisms are provided for different pixel arrays in the pixel arrays of the acceptor substrate.

8. The transfer apparatus according to claim 3, wherein light permeability in an aperture provided in a center portion of the radiation ray splitter is set to be lower than that in an aperture provided in an end portion.

9. A method of manufacturing an organic light emitting element having a red organic light emitting region, a green organic light emitting region, and a blue organic light emitting region on a substrate, comprising the steps of:
disposing a transfer substrate and a device substrate so as to face each other, a transfer layer containing a light emitting material being provided on the transfer substrate, and a plurality of device formation areas being arranged in the device substrate; and
transferring the transfer layer to the plurality of device formation areas by emitting a radiation ray from the transfer substrate side,
wherein,
the radiation ray is shaped in a band shape, and a intensity peak value in a center portion in a long-axis direction of the radiation ray is set to be smaller than that in an end portion.
